(19) United States
(12) Patent Application Publication
(10) Pub. No.: US 2024/0178105 A1
(43) Pub. Date: May 30, 2024

(54) METHOD OF MANUFACTURING SUBSTRATES FOR SEMICONDUCTOR DEVICES, CORRESPONDING PRODUCT AND SEMICONDUCTOR DEVICE

(71) Applicant: STMICROELECTRONICS S.r.l., Agrate Brianza (IT)

(72) Inventors: Roberto TIZIANI, NERVIANO (IT); Mauro MAZZOLA, Calvenzano (IT)

(73) Assignee: STMICROELECTRONICS S.r.l., Agrate Brianza (IT)

(21) Appl. No.: 18/516,707

(22) Filed: Nov. 21, 2023

(30) Foreign Application Priority Data
Nov. 30, 2022 (IT) 102022000024678

(51) Int. Cl. H01L 23/495; H01L 21/48; H01L 21/56; H01L 23/31

(52) U.S. Cl. CPC H01L 23/49541; H01L 21/4828; H01L 21/56; H01L 23/3107; H01L 24/32; H01L 2224/32245

(57) ABSTRACT

Electrically insulating material such as an epoxy resin is molded onto a sculptured, electrically conductive leadframe structure comprising a pattern of electrically conductive formations. The electrically insulating material penetrates into spaces between electrically conductive formations in the pattern of electrically conductive formations to provide a pre-molded leadframe structure configured to have at least one semiconductor die arranged thereon. The pre-molded leadframe structure has opposed first and second surfaces and a pre-molded leadframe thickness between the first surface and the second surface. The sculptured, electrically conductive leadframe structure comprises one or more connection formations connected with electrically conductive formations in the pattern of electrically conductive formations. The connection formation or formations have a first thickness equal to the thickness between the first surface and the second surface. The thickness of the connection formation or formations is reduced from the first thickness to a second, reduced uniform thickness with exposed wettable flanks formed in the electrically conductive formations facing the connection formation or formations with reduced thickness.

### BACKGROUND

### Technical Field

The description relates to manufacturing semiconductor devices.

### Description of the Related Art

Current manufacturing processes of semiconductor devices may take advantage of so-called pre-molded leadframes, that is substrates comprising a sculptured, electrically conductive (e.g., metal) structure formed from a metal sheet and comprising empty spaces that are filled by an insulating resin “pre-molded” on the sculptured electrically conductive structure.

A plurality of leadframes, kept together by connecting bars in a leadframe strip can be processed concurrently to be finally “singulated” into individual devices.

A second etching of the leadframe and connecting bars is performed to provide the leadframe with wettable flanks (WFs).

These are features at the periphery of the leadframe that facilitate soldering the device on a substrate (e.g., a PCB) by forming a solder meniscus. For instance, wettable flanks are modifications to the exposed terminal ends, which promote solder wetting for the formation of a solder fillet that is visible.

The conventional sequence of two etching steps may lead to surfaces of the connecting bars which may give rise to irregularly shaped wettable flanks. In addition, singulation into individual devices may be more difficult and less precise due to these imperfections.

### BRIEF SUMMARY

As described herein, the present disclosure is directed at addressing the issues discussed in the foregoing.

One or more embodiments relate to a corresponding product (a pre-molded leadframe).

One or more embodiments relate to a corresponding semiconductor device (obtainable, e.g., using such a pre-molded leadframe).

As described herein, the present disclosure is directed to modifying current etching processes to achieve a flatter and more regular surface of the connecting bars.

As described herein, the present disclosure is directed to facilitating forming wettable flanks which are exempt from irregularities and residuals from the connecting bars.

### BRIEF DESCRIPTION OF THE SEVERAL VIEWS OF THE DRAWINGS

One or more embodiments will now be described, by way of example only, with reference to the annexed figures, wherein:

FIG. 1 is a plan view illustrative of the structure of a power semiconductor device being manufactured,

FIGS. 2, 3, 4A and 4B are enlarged views of the portion of FIG. 1 indicated by the arrow II represented at various stages of a manufacturing process of pre-molded leadframes,

FIGS. 5 and 6 are more realistic representations of a portion of a leadframe in a perspective and a plan view, respectively,

FIGS. 7, 8, 9A and 9B are enlarged views of the portion of FIG. 1 indicated by the arrow II represented at various processing steps according to the present description.

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

### DETAILED DESCRIPTION

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description, and unless the context indicates otherwise, like parts or elements are indicated in the various figures with like reference signs, and a corresponding description will not be repeated for each and every figure.

As described herein, various embodiments and discussions of the present disclosure can be applied, for instance, to manufacturing substrates (leadframes) for semiconductor devices including integrated circuits (ICs) such as power QFN packages, for automotive or industrial products, for instance.

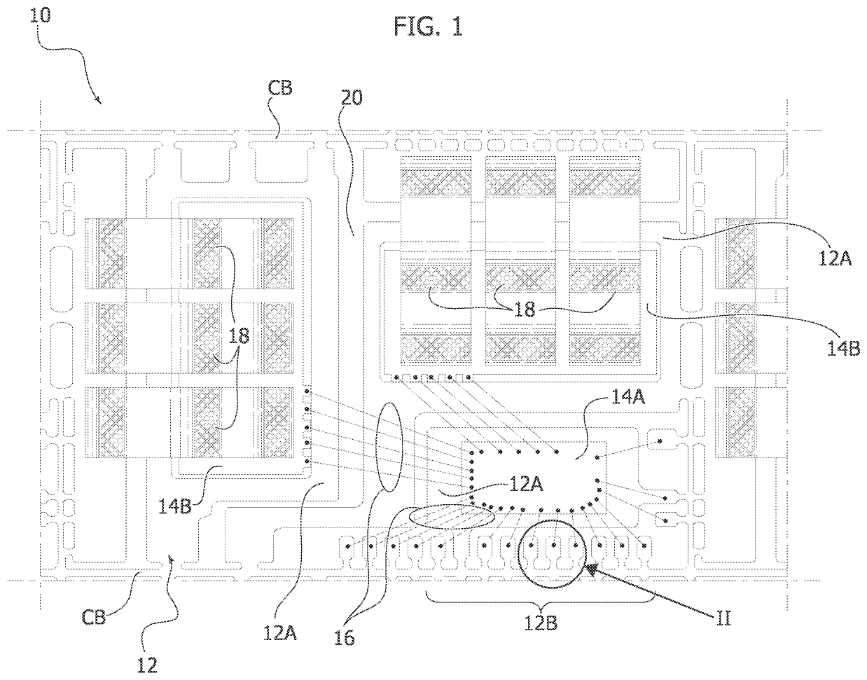

FIG. 1 illustrates the structure of a power semiconductor device 10 comprising a low-power section and a high-power section.

The power semiconductor device 10 comprises a leadframe 12 having a number of die pads 12A and an array of electrically conductive leads 12B.

The low-power section of the device 10 comprises a controller die or chip 14A, which is or includes an integrated circuit, attached on a first die pad 12A. As exemplified in FIG. 1, the high-power section comprises two power (integrated circuit) dice or chips 14B attached on two other die pads 12A in the leadframe 12.

Electrical coupling of the controller die or chip 14A, to the power dice or chips 14B is via wire bonding patterns 16.

So-called ribbons 18 provide conduction lines from the power dice or chips 14B to output pads of the device 10 as provided by leads 12B is arranged around the die pads 12A.

As discussed so far, the overall structure of the semiconductor device 10 illustrated in FIG. 1 can be regarded as conventional in the art, which makes it unnecessary to provide a more detailed description herein.

The semiconductor device 10 illustrated in FIG. 1 otherwise merely represents a non-limiting example of a semiconductor device comprising a substrate (leadframe) 12 having one or more semiconductor chips or dice 14A, 14B (as used herein, the terms chip/s and die/dice are regarded as synonymous) arranged thereon as well as electrically conductive formations such as wires, ribbons (or clips) 16, 18 coupling the semiconductor chip(s) 14A, 14B to leads (outer pads) 12B in the substrate.

The designation “leadframe” (or “lead frame”) is currently used and may include the details from the USPC Consolidated Glossary of the United States Patent and Trademark Office). For example, the designation “leadframe,” may be to indicate a metal frame that provides support for an integrated circuit chip or die as well as electrical leads to interconnect the integrated circuit in the die or chip to other electrical components or contacts. Furthermore, the designation “leadframe,” covers current industry standards, as well as other similar or like structures.

Essentially, a leadframe 12 comprises an array of electrically-conductive formations (or leads, e.g., 12B) that from an outline location extend inwardly in the direction of one or more semiconductor chips or dice (e.g., 14A and 14B) thus forming an array of electrically-conductive formations from one or more die pads (e.g., 12A in FIG. 1) configured to have at least one semiconductor chip or die attached thereon. This may be via conventional means such as a die attach adhesive (a die attach film or DAF, for instance).

The leadframe 12 illustrated in FIG. 1 is of the pre-molded type, that is a type of leadframe comprising a sculptured metal (e.g., copper) structure formed by etching a metal sheet to provide the die pads 12A and the leads 12B and comprising empty spaces that are filled by a resin 20 (e.g., an epoxy resin) “pre-molded” on the sculptured metal structure.

A manufacturing process of a pre-molded leadframe as exemplified in FIG. 1 may comprise three steps: a first etching step, where a metal (e.g., copper) sheet is (photo-)etched on both sides (top/front and bottom/back sides) to bestow a desired shape on the leadframe 12 by forming the die pads and the leads 12B, a pre-molding step, where the empty spaces in the leadframe (for example, between the die pads 12A and the leads 12B) are filled with an insulating pre-molding resin 20 thus promoting the adhesion of the parts of the leadframe, and a second etching step, where the pre-molded leadframe is half-etched on the bottom/back side to form so-called wettable flanks, that are undercuts at the periphery of the bottom/back surface of die pads and leads: the wettable flanks are intended to facilitate soldering of the device to a substrate (a printed circuit board, PCB, for example, not visible in the figures).

It is noted that “half-etching” is a common designation in the art, which does not imply that such partial etching is by necessity to exactly half the thickness of the base sculptured structure of the leadframe.

As illustrated in FIG. 1 (top and bottom), connecting bars CB are formed in the first etching step in order to maintain pads 12A and leads 12B at desired positions, form a structure able to resist to the pre-molding pressure.

Connecting bars CB are also used to connect two different leadframes in a leadframe strip. In fact, in current manufacturing processes of semiconductor devices, plural devices are manufactured concurrently starting from a leadframe strip, and later separated into single individual devices in a final singulation step.

Such a final singulation step can be performed using a blade, for example, that removes the connecting bars CB thus concurrently separating two neighboring leadframes and the leads within the same leadframe.

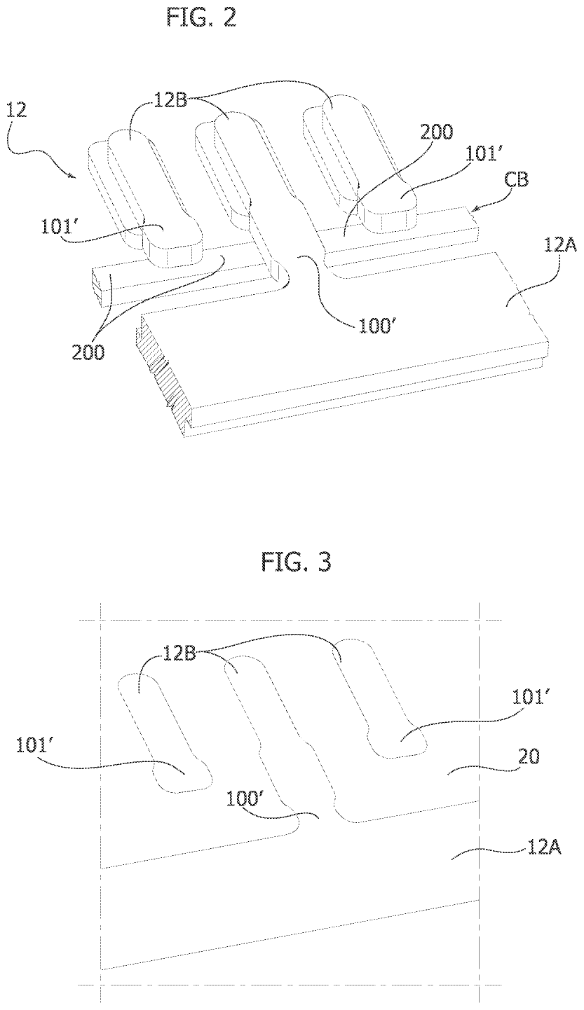

FIG. 2 is an enlarged view of the back/bottom side of a leadframe portion (for example, the region indicated by the arrow II in FIG. 1) formed via a first etching step.

It is observed that different regions of the leadframe 12 may have different thicknesses. For instance (see primarily FIG. 2) a portion 101′ of the leads 12B, at least partially overlapping with the connecting bar CB, and the bridge-like formation 100′ to a die pad 12A in a neighboring device in the leadframe strip have a “full” thickness, while the rest of the connecting bar CB (the regions indicated with 200) have “half” thickness.

FIG. 3 illustrates the result of the pre-molding step, wherein a pre-molding resin 20 is molded (e.g., transfer-molded) onto the leadframe 12 to fill the gaps formed by the first etching step.

As illustrated, only the formations with full thickness, namely the region 100′ and 101′ (in addition to the leads 12B and die pad 12A), are visible at the bottom/back surface of the leadframe once pre-molded.

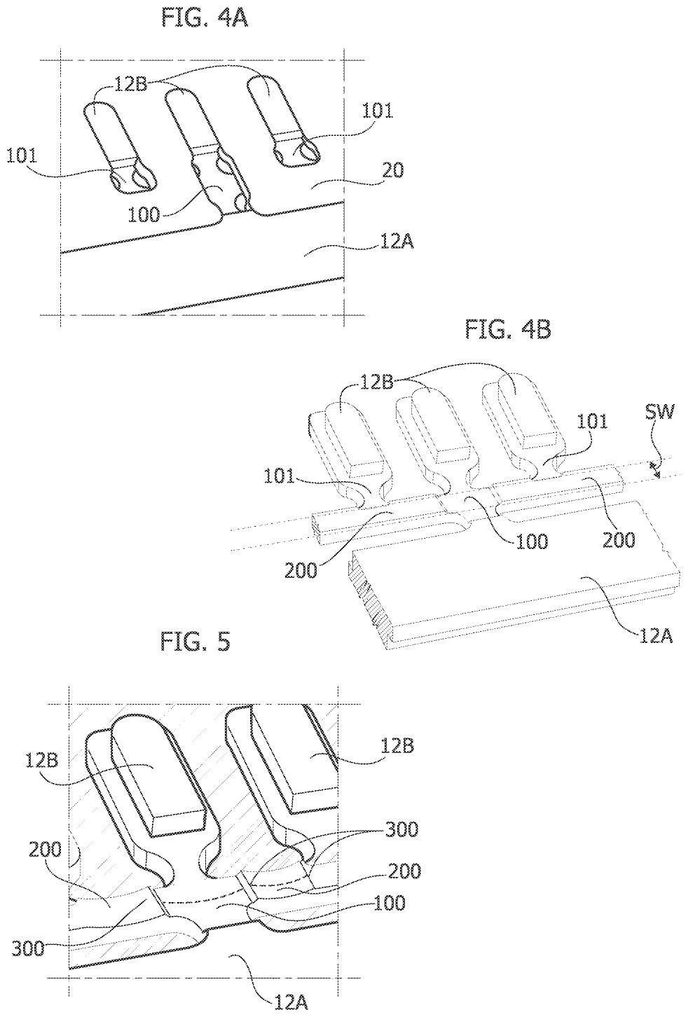

FIGS. 4A and 4B are illustrative of a second etching step intended to form wettable flanks.

FIG. 4A shows the bottom/back surface of the leadframe after the second etching step while FIG. 4B illustrates the same leadframe of FIG. 4A with the pre-molding resin virtually removed (that is, not shown for clarity): FIG. 4B is only intended to help the reader in better visualizing the result of the second etching step and it does not/may not describe an actual step in pre-molded leadframe manufacturing process.

As illustrated in the FIGS. 4A and 4B, metal (copper) material is partially removed (half-etched, via photo-etching, for example) in the regions 100′, 101′ thus creating the regions now indicated as 100, 101.

As it may be observed in FIG. 4B, regions 200, 100 and 101 have approximately the same reduced (half) thickness.

In FIG. 4B is also illustrative of the sawing line (of width SW) of the final singulation: after the singulation cut, the half-etched regions 100 and 101 will form the wettable flanks

Processing as discussed so far is conventional in the art, which makes it unnecessary to provide a more detailed description herein.

Such processing may undesirably lead to irregularly shaped leadframes.

FIG. 5 aims at depicting the actual appearance of the bottom/back surface of a “real” leadframe obtained via the process illustrated in the foregoing based on the schematic representation of FIGS. 2 to 4.

FIG. 5 thus illustrates a more realistic representation in comparison with FIG. 4B, that is a pre-molded leadframe where the pre-molding resin 20 has been removed. Again, this figure does not necessarily describe a processing step, and it is intended to simplify the description of such a pre-molded leadframe.

The bent dashed lines in the regions 100 and 200 serve as a guide to the eye to better appreciate the irregularity of the surface of those regions; this surface irregularity is an intrinsic result of the photo-etching technique employed to form these regions, with etching more evident at the central portion (of the region 200, for example) than in the peripheral part, thus forming a curved (rather than flat) surface, as highlighted by the dashed lines.

Moreover, as a result of being formed (etched) in two different steps (the first etching step and the second etching step, respectively) the two regions 200, 100 may have slightly different thicknesses.

A curvature of the surface of the regions 100 and 200 and/or small differences in the resulting thicknesses may result in the excess of material (e.g., copper) accumulating in the border region between the two regions 100 and 200 thus forming a fillet 300 therein.

The presence of such a fillet 300 and, in general, the irregularity of the surface of the connecting bar CB may be visible even after the connecting bar CB has been removed in the singulation step.

In fact, a small misalignment of the singulation blade during the singulation step may result in irregularities on wettable flanks surface and may adversely affect their role in facilitating soldering the device to a substrate (e.g., a PCB). Current precision in the positioning of the blade (about 25 micron) may not be sufficient to ensure that wettable flanks are exempt from these irregularities.

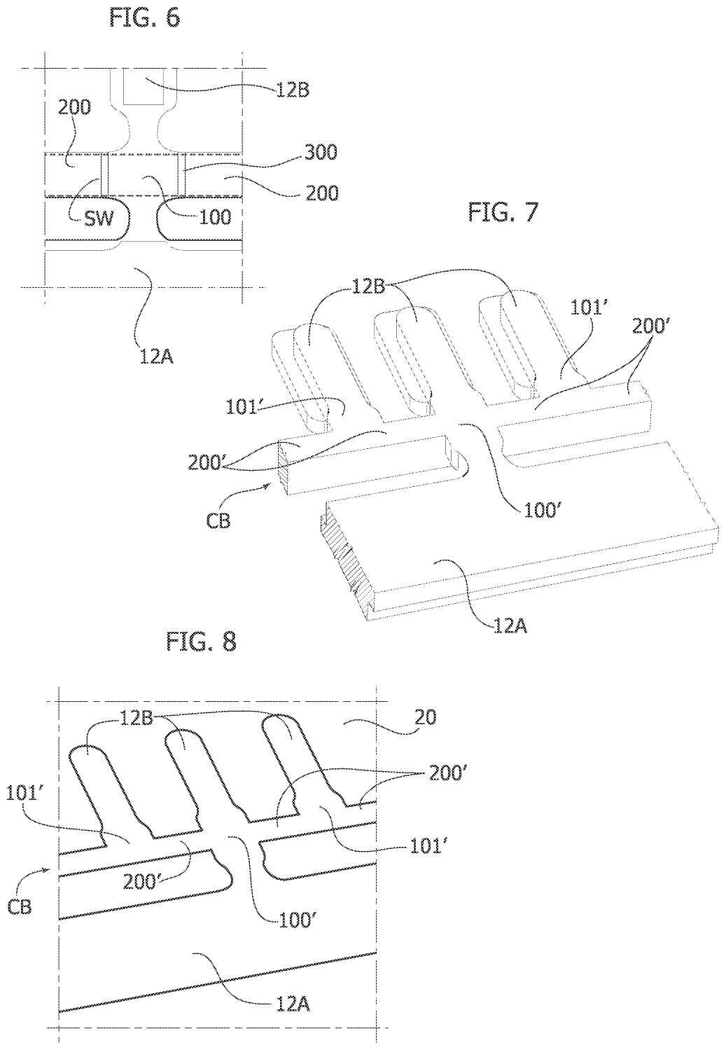

FIG. 6 further illustrates the effects of a (small) misalignment of the blade in the singulation step.

It is observed that, due to the accumulation of material therein, in the presence of an (even small) departure from the exact position indicated the dashed lines SW, the ends of the fillets 300 may remain after the singulation step. Irregularities of the connecting bars may also render the singulation step more complex and possibly less precise.

In principle, the flatness of the connecting bars could be improved by an increased control over the etching process or by increasing the accuracy in positioning the blade by aligning it manually; however, these solutions are complex and hardly adapted to be applied in industrial scale processes.

As described herein, the present disclosure is directed at addressing the issues discussed so far and above by reducing the irregularities in the surface of the connecting bars CB via an alternative manufacturing process of pre-molded leadframes.

As described herein, the various embodiments of the present disclosure do not rely on an increased control of the photo-etching technique or an increased accuracy in the singulation step and can be applied without modification in the manufacturing apparatus.

To summarize, embodiments as discussed herein (also in connection with the following figures) relate to techniques wherein electrically insulating material 20 (e.g., an epoxy resin) is molded onto a sculptured, electrically conductive leadframe structure comprising a pattern of electrically conductive formations such as die pads 12A and arrays of leads 12B.

The electrically insulating material 20 penetrates into the spaces between the electrically conductive formations to provide a pre-molded leadframe structure configured to have one or more semiconductor dice 14A, 14B arranged thereon.

The pre-molded leadframe structure thus has opposed first and second surfaces and a (first) pre-molded leadframe thickness between the first surface and the second surface.

The sculptured, electrically conductive leadframe structure comprises at least one connection formation (connecting bar) CB connected (at the connection regions 100′, 101′) with electrically conductive formations 12A, 12B in the pattern of electrically conductive formations.

In arrangements as discussed so far (see, e.g., FIG. 2) the connection formation CB is formed from the outset—during production of the sculptured structure of the leadframe 12—with a thickness that is smaller (e.g., approximately half) than the thickness of the pads 12A and the leads 12B.

Conversely, in solutions as proposed herein (see, e.g., FIG. 7), the connection formation CB is formed at the outset—during production of the sculptured structure of the leadframe 12—with a thickness that is equal to the thickness of the pads 12A and the leads 12B, that is having a first thickness equal to the thickness between the first surface and the second surface of the pre-molded leadframe.

The thickness of the connection formation CB is then reduced (e.g., via selective material removal, optionally via etching) from such a first thickness to a second, reduced thickness so that exposed wettable flanks are formed in the electrically conductive formations 12A, 12B facing the connection formation CB with reduced thickness.

FIG. 7 illustrates a region of the back/bottom surface (second surface) of a leadframe 12 obtained via a first etching step according to the present description: there, leads 12B are initially connected via a connecting bar CB which has the full thickness of the starting metallic (e.g., copper) sheet.

Comparing FIG. 7 with FIG. 2 one may note that in the case illustrated in FIG. 7 the connecting bars CB, the bridge-like formation 100′, the leads 12B and the die pad 12A have the same (full) thickness, in contrast to the case illustrated in FIG. 2 wherein the regions 200 of the connecting bars CB have a reduced (“half”) thickness.

FIG. 8 illustrates the result of the pre-molding step applied to the leadframe illustrated in FIG. 7.

In this case, in comparison with FIG. 3, the whole connecting bar CB is visible at the bottom/back surface of the pre-molded resin 20 and accessible to be etched in the second etching step.

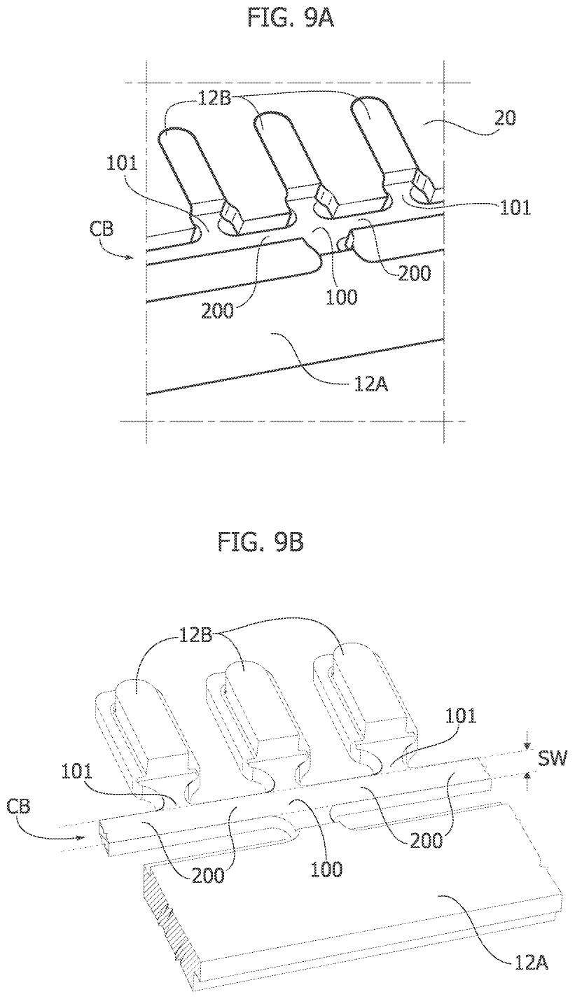

FIGS. 9A and 9B illustrate the result of such an etching step. As before, FIG. 9B illustrates the same leadframe of FIG. 9A after the (fictitious) removal of the pre-molding resin 20 and is not intended to describe an actual processing step.

This second etching step etches away material from the bottom/back of the leadframe 12 reducing the thickness (half-etching) of the whole connecting bar CB, that is in the regions indicated as 100, 101 and 200.

Regions 100 and 101 will form the wettable flanks of the device once the singulation performed (for example, by sawing along the dashed lines SW of FIG. 9B).

Since the half-etched regions 100, 101 and 200 have been formed via the same etching step, they will have a flatter and more regular surface, that is a reduced uniform thickness.

In fact, accumulation of material at the border of the regions 100 and 200 (or 101 and 200), and the consequent formation of a fillet (see, for example, 300 in FIG. 5) is countered by etching the regions 100, 101 and 200 to the same depth.

For instance, the reduced (uniform) second thickness may be approximately half the first thickness of the pre-molded leadframe. As used herein, “approximately half” is intended to mean as referring to a value a skilled person in the field of manufacturing semiconductor devices would consider to be a half.

It will be appreciated that etching these regions 100, 101 and 200 at the same depth does not require a more accurate etching apparatus.

A product such as a pre-molded leadframe as discussed herein lends itself to being completed to a semiconductor device by arranging one or more semiconductor dice (see, e.g., 14A, 14B in FIG. 1) on the die pads 12A of the pre-molded leadframe structure.

The pre-molded leadframe structure can be cut at the connection formations CB removing these connection formations CB (with reduced thickness).

Advantageously, the semiconductor dice 14A, 14B are arranged on the pre-molded leadframe structure, which is then cut at the connection formation(s) CB.

For instance, the pre-molded leadframe structure may comprises a plurality of leadframe sections (e.g., in a strip) separated by connection formations CB extending therebetween.

These leadframe sections comprise patterns of electrically conductive formations (e.g., die pads 12A) configured to have respective semiconductor dice 14A, 14B arranged thereon.

Once these semiconductor dice 14A, 14B are arranged at the electrically conductive formations 12A in the plurality (e.g., strip) of leadframe sections, the pre-molded leadframe structure with respective semiconductor dice (14A, 14B) arranged thereon can be cut at the connection formations extending therebetween to provide singulated semiconductor devices.

These resulting semiconductor devices will thus comprise one or more semiconductor dice 14A, 14B arranged thereon with the connection formation(s) CB) with reduced, uniform thickness removed and the wettable flanks in the electrically conductive formations (e.g., leads 12B) left exposed, e.g., to promote solder wetting for the formation of a solder fillet that is visible when the device is mounted on support such as a printed circuit board (PCB).

Due to the flatter and more regular surface of the connecting bars CB, the risk of having an irregular surface of the wettable flanks, as a consequence of a small misalignment of the blade during the singulation step, is reduced or prevented.

Moreover, since the blade acts through a homogenous material (almost no resin 20 is left on the connecting bar), the singulation step will be easier and will deteriorate less the blade.

A method of the present disclosure may be summarized as including: molding electrically insulating material (20) onto a sculptured, electrically conductive leadframe structure comprising a pattern of electrically conductive formations (12A, 12B), wherein electrically insulating material (20) penetrates into spaces between electrically conductive formations (12A, 12B) in the pattern of electrically conductive formations (12A, 12B) to provide a pre-molded leadframe structure configured to have at least one semiconductor die (14A, 14B) arranged thereon, the pre-molded leadframe structure having opposed first and second surfaces and a pre-molded leadframe thickness between the first surface and the second surface, wherein the sculptured, electrically conductive leadframe structure comprises at least one connection formation (CB) connected (100′, 101′) with electrically conductive formations (12A, 12B) in the pattern of electrically conductive formations, the at least one connection formation (CB) having a first thickness equal to said thickness between the first surface and the second surface, and reducing the thickness of the at least one connection formation (CB) from the first thickness to a second, reduced thickness with exposed wettable flanks formed in the electrically conductive formations (12A, 12B) in the pattern of electrically conductive formations facing the at least one connection formation (CB) with reduced thickness.

Reducing the thickness of the at least one connection formation (CB) from the first thickness to the second thickness may include partially removing material from the second surface of the pre-molded leadframe structure.

Removing material from the second surface of the pre-molded leadframe structure may be accomplished via photo-etching.

The reduced second thickness may be approximately half said first thickness.

The method may include arranging at least one semiconductor die (14A, 14B) on said pre-molded leadframe structure.

The method may include cutting the pre-molded leadframe structure at the at least one connection formation (CB) removing the at least one connection formation (CB) with reduced thickness.

The method may include: arranging at least one semiconductor die (14A, 14B) on said pre-molded leadframe structure, and cutting at the at least one connection formation (CB) the pre-molded leadframe structure having at least one semiconductor die (14A, 14B) arranged thereon.

The pre-molded leadframe structure may include a plurality of leadframe sections separated by connection formations (CB) extending therebetween, the plurality of leadframe sections including patterns of electrically conductive formations (12A, 12B) configured to have respective semiconductor dice (14A, 14B) arranged thereon, wherein the method may include: arranging respective semiconductor dice (14A, 14B) at the patterns of electrically conductive formations (12A, 12B) in said plurality of leadframe sections in said pre-molded leadframe structure, and cutting the pre-molded leadframe structure having at respective semiconductor dice (14A, 14B) arranged at the patterns of electrically conductive formations (12A, 12B) at said connection formations (CB) extending therebetween to provide singulated semiconductor devices.

A product of the present disclosure may be summarized as including: electrically insulating material (20) molded onto a sculptured, electrically conductive leadframe structure comprising a pattern of electrically conductive formations (12A, 12B), wherein electrically insulating material (20) penetrates into spaces between electrically conductive formations (12A, 12B) in the pattern of electrically conductive formations (12A, 12B) and provides a pre-molded leadframe structure configured to have at least one semiconductor die (14A, 14B) arranged thereon, the pre-molded leadframe structure having opposed first and second surfaces and a pre-molded leadframe thickness between the first surface and the second surface, wherein the sculptured, electrically conductive leadframe structure comprises at least one connection formation (CB) connected (100′, 101′) with electrically conductive formations (12A, 12B) in the pattern of electrically conductive formations, wherein the at least one connection formation (CB) has a reduced uniform thickness smaller than the pre-molded leadframe thickness between the first surface and the second surface and exposed wettable flanks formed in the electrically conductive formations (12A, 12B) in the pattern of electrically conductive formations facing the at least one connection formation (CB) with said second reduced thickness.

The reduced uniform thickness may be approximately half said pre-molded leadframe thickness between the first surface and the second surface.

A semiconductor device of the present disclosure may be summarized as including: the product as described directly above with the at least one connection formation (CB) with reduced uniform thickness removed and said wettable flanks in the electrically conductive formations (12A, 12B) in the pattern of electrically conductive formations exposed, and at least one semiconductor die (14A, 14B) arranged on said pre-molded leadframe structure (12A).

Without prejudice to the underlying principles, the details and embodiments may vary, even significantly, with respect to what has been described by way of example only without departing from the extent of protection. The extent of protection is determined by the annexed claims.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
molding electrically insulating material onto a sculptured, electrically conductive leadframe structure comprising a pattern of electrically conductive formations, wherein electrically insulating material penetrates into spaces between electrically conductive formations in the pattern of electrically conductive formations to provide a pre-molded leadframe structure configured to have at least one semiconductor die arranged thereon, the pre-molded leadframe structure having opposed first and second surfaces and a pre-molded leadframe thickness between the first surface and the second surface, wherein the sculptured, electrically conductive leadframe structure comprises at least one connection formation connected with electrically conductive formations in the pattern of electrically conductive formations, the at least one connection formation having a first thickness equal to said thickness between the first surface and the second surface; and
reducing the thickness of the at least one connection formation from the first thickness to a second, reduced thickness with exposed wettable flanks formed in the electrically conductive formations in the pattern of electrically conductive formations facing the at least one connection formation with reduced thickness.

2. The method of claim 1, wherein reducing the thickness of the at least one connection formation from the first thickness to the second thickness comprises partially removing material from the second surface of the pre-molded leadframe structure.

3. The method of claim 2, wherein removing material from the second surface of the pre-molded leadframe structure may be accomplished via photo-etching.

4. The method of claim 1, wherein the reduced second thickness is approximately half said first thickness.

5. The method of claim 1, comprising arranging at least one semiconductor die on said pre-molded leadframe structure.

6. The method of claim 1, comprising cutting the pre-molded leadframe structure at the at least one connection formation removing the at least one connection formation with reduced thickness.

7. The method of claim 5, comprising:
arranging at least one semiconductor die on said pre-molded leadframe structure, and
cutting at the at least one connection formation the pre-molded leadframe structure having at least one semiconductor die arranged thereon.

8. The method of claim 7, wherein the pre-molded leadframe structure comprises a plurality of leadframe sections separated by connection formations extending therebetween, the plurality of leadframe sections comprising patterns of electrically conductive formations configured to have respective semiconductor dice arranged thereon,
wherein the method comprises:
arranging respective semiconductor dice at the patterns of electrically conductive formations in said plurality of leadframe sections in said pre-molded leadframe structure, and
cutting the pre-molded leadframe structure having at respective semiconductor dice arranged at the patterns of electrically conductive formations at said connection formations extending therebetween to provide singulated semiconductor devices.

9. A product, comprising:
electrically insulating material molded onto a sculptured, electrically conductive leadframe structure comprising a pattern of electrically conductive formations, wherein electrically insulating material penetrates into spaces between electrically conductive formations in the pattern of electrically conductive formations and provides a pre-molded leadframe structure configured to have at least one semiconductor die arranged thereon, the pre-molded leadframe structure having opposed first and second surfaces and a pre-molded leadframe thickness between the first surface and the second surface, wherein the sculptured, electrically conductive leadframe structure comprises at least one connection formation connected with electrically conductive formations in the pattern of electrically conductive formations,
wherein the at least one connection formation has a reduced uniform thickness smaller than the pre-molded leadframe thickness between the first surface and the second surface and exposed wettable flanks formed in the electrically conductive formations in the pattern of electrically conductive formations facing the at least one connection formation with said second reduced thickness.

10. The product of claim 9, wherein the reduced uniform thickness is approximately half said pre-molded leadframe thickness between the first surface and the second surface.

11. A method, comprising:
forming a molding compound including:
covering first sidewalls of a one or more lead portions of a leadframe structure, and leaving first surfaces of the one or more lead portions transverse to the first sidewalls exposed from the molding compound;
covering second sidewalls of a connecting bar of the leadframe structure, the connecting bar being coupled to the one or more lead portions of the leadframe structure, and leaving a second surface of the connecting bar transverse to the second sidewalls exposed from the molding compound;
etching the leadframe structure including:
forming a flat continuous surface recessed from the first surfaces of the one or more lead portions and extending along the one or more lead portions and the connecting bar by removing first portions of the one or more lead portions and a second portion of the connecting bar.

12. The method of claim 11, wherein forming the molding compound further includes covering third sidewalls of a die pad of the leadframe structure, the die pad being coupled to the connecting bar of the leadframe structure, and leaving a third surface of the die pad transverse to the third sidewalls exposed from the molding compound.

13. The method of claim 11, wherein forming the continuous surface further includes removing a third portion of the leadframe structure that couples the die pad to the connecting bar.

14. The method of claim 11, further comprising singulating along the connecting bar.

15. The method of claim 14, wherein the singulating along the connecting bar includes sawing along the connecting bar.

16. The method of claim 15, further comprising coupling a die to the die pad before singulating along the connecting bar.

17. The method of claim 15, wherein singulating along the connecting bar includes singulating along the flat continuous surface reducing or preventing forming an irregular wettable flank of a lead.

18. The method of claim 11, further comprising coupling a die to the die pad.

19. The method of claim 18, further comprising forming a plurality of wires coupled to the die.

20. The method of claim 11, wherein the first portions of the lead portions and the second portion of the connecting bar are continuous with each other.
